(19) United States
(12) Patent Application Publication
(10) Pub. No.: US 2026/0333715 A1
(43) Pub. Date: Oct. 22, 2026

(54) COMPUTING SYSTEMS INCORPORATING HIGH-BANDWIDTH MRAM MEMORY STACKS

(71) Applicant: TetraMem Inc., Fremont, CA (US)

(72) Inventors: Ning Ge, Danville, CA (US); Minxian Zhang, Amherst, MA (US)

(73) Assignee: TetraMem Inc., Fremont, CA (US)

(21) Appl. No.: 19/183,704

(22) Filed: Apr. 18, 2025

(51) Int. Cl. H10B 99/00; H01L 23/498; H01L 23/535; H01L 25/00; H01L 25/18; H10B 80/00

(52) U.S. Cl. CPC H10B 99/10; H10B 80/00; H10W 20/20; H10W 90/00; H10W 90/701

(57) ABSTRACT

The present disclosure provides for computing systems incorporating high bandwidth in-memory computing stacks. A computing system may include a processing die and a magneto-resistive random-access memory (MRAM) stack connected to an interposer. The MRAM stack may include a plurality of vertically stacked MRAM dies for performing non-volatile memory and/or in-memory computing. Each of the MRAM dies may include one or more crossbar arrays configured to perform non-volatile memory and/or in-memory computing. Each of the plurality of crossbar arrays may include a plurality of bit lines, a plurality of word lines, and a plurality of cross-point devices at intersections of the plurality of word lines and the plurality of bit lines. Each of the cross-point devices may include one or more MRAM devices. In some embodiments, the computing system may further include vertically stacked dynamic random-access memory (DRAM) arrays, flash memory arrays. and/or resistive random-access memory (RRAM) arrays.

### TECHNICAL FIELD

The implementations of the disclosure relate generally to computing systems and, more specifically, to computing systems incorporating high-bandwidth magneto-resistive random-access memory (MRAM) stacks for high-performance computing and/or in-memory computing applications with high energy efficiency.

### BACKGROUND

Artificial intelligence (AI) systems typically operate in two stages. The first stage, known as training or teaching, may involve instructing a neural network (e.g., a convolutional neural network (CNN), recurrent neural network (RNN), deep neural network (DNN), etc.) to learn from examples rather than being explicitly programmed. Factors that influence the training process include the training data, the chosen algorithm, and the availability of high-performance computing resources such as GPUs and sufficient memory. The second stage is inference (or prediction), during which the inference system can use lower-performance chips than those required for the training stage. Existing AI systems typically include on-chip memory, such as SRAM, that stores data being actively processed and off-chip DRAM memory that stores the larger dataset. Notably, significant time consumption and power consumption may occur during data transfer between processors and off-chip memory.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

According to one or more aspects of the present disclosure, a computing system is provided. The computing system includes: a processing die connected to an interposer; and a magneto-resistive random-access memory (MRAM) stack connected to the interposer. The MRAM stack includes: a plurality of vertically stacked MRAM dies, wherein each of the plurality of vertically stacked MRAM dies includes one or more crossbar arrays configured to perform at least one of non-volatile memory or in-memory computing. Each of the crossbar arrays includes a plurality of bit lines, a plurality of word lines, and a plurality of cross-point devices at intersections of the plurality of word lines and the plurality of bit lines, wherein each of the cross-point devices includes at least one MRAM device.

In some embodiments, the plurality of vertically stacked MRAM dies are configured to implement a neural network, wherein a first MRAM die of the plurality of vertically stacked MRAM dies receives an input analog signal, and wherein a second MRAM die of the plurality of vertically stacked MRAM dies produces an output analog signal representing a processing result of the input analog signal after being processed by the neural network.

In some embodiments, a cross-point device of the plurality of cross-point devices includes an MRAM device configured to store single-bit data or a single-bit weight.

In some embodiments, the plurality of cross-point devices includes a plurality of MRAM devices configured to store multi-bit data or a multi-bit weight, wherein each of the plurality of MRAM devices is configured to store a binary bit, and wherein the multi-bit data or the multi-bit weight corresponds to a combination of a plurality of binary bits stored in the plurality of MRAM devices.

In some embodiments, the plurality of vertically stacked MRAM dies is vertically stacked on a logic die, wherein the logic die is connected to the interposer through a first physical layer block.

In some embodiments, the logic die is connected to the second MRAM die through a plurality of interconnects.

In some embodiments, the logic die includes an analog-to-digital converter that converts the output analog signal into a digital signal.

In some embodiments, the analog-to-digital converter further provides the digital signal to the processing die through the first physical layer block.

In some embodiments, the processing die is connected to the interposer through a second physical layer block.

In some embodiments, the first MRAM die includes a digital-to-analog converter.

In some embodiments, the processing die includes at least one of a central processing unit, a graphics processing unit, or an application-specific integrated circuit for performing machine learning.

In some embodiments, adjacent MRAM dies of the plurality of MRAM dies are connected through a plurality of interconnects, wherein the plurality of interconnects includes through-silicon vias (TSVs).

In some embodiments, the plurality of interconnects further includes a plurality of micro-bumps.

In some embodiments, the computing system further includes a plurality of vertically stacked HBM (High-Bandwidth Memory) dies connected to the processing die, wherein each of the plurality of vertically stacked HBM dies includes DRAM (dynamic random-access memory) devices, and wherein the HBM dies are configured to perform low-latency processing of time-sensitive or data-intensive operations.

In some embodiments, the computing system further includes a plurality of stacked HBF (High-Bandwidth Flash) dies, wherein each of the HBF dies includes flash memory devices.

In some embodiments, the plurality of vertically stacked MRAM dies is configured to perform non-volatile memory, in-memory computing, and deep neural network processing, wherein the plurality of stacked HBM dies are configured to store frequently accessed data or weights of a neural network, and wherein the plurality of stacked HBF dies are configured to store high volume less frequently accessed data or weights of the neural network.

In some embodiments, the computing system further includes a plurality of vertically stacked resistive random-access memory (RRAM) dies connected to the interposer.

According to one or more aspects of the present disclosure, a method is provided. The method includes bonding a first magneto-resistive random-access memory (MRAM) wafer and a second MRAM wafer to form a wafer stack, wherein each of the first MRAM wafer and the second MRAM wafer includes one or more crossbar arrays configured to perform non-volatile memory and in-memory computing operations, and wherein each of the one or more crossbar arrays includes a plurality of bit lines, a plurality of word lines, and a plurality of MRAM devices at intersections of the plurality of word lines and the plurality of bit lines; and dicing the wafer stack into a plurality of MRAM dies.

In some embodiments, the method further includes forming a die underfill between the bonded first MRAM wafer and the second MRAM wafer.

In some embodiments, bonding the first MRAM wafer and the second MRAM wafer includes: fabricating a plurality of through-silicon vias (TSVs) in the first MRAM wafer and the second MRAM wafer; fabricating micro-pads on the plurality of TSVs; and bonding the first MRAM wafer and the second MRAM wafer through the micro-pads and micro-bumps.

### BRIEF DESCRIPTION OF THE DRAWINGS

The disclosure will be more fully understood from the detailed description given below and from the accompanying drawings of various embodiments of the disclosure. The drawings, however, should not be taken to limit the disclosure to the specific embodiments, but are for explanation and understanding.

FIGS. 1A and 1B are schematic diagrams illustrating a side view and a top view of an example computing system incorporating high-bandwidth magneto-resistive random-access memory (MRAM) stacks in accordance with some embodiments of the present disclosure.

FIG. 2 is a diagram illustrating an example of a crossbar array in accordance with some embodiments of the present disclosure.

FIG. 3 is a schematic diagram illustrating a perspective view of an example MRAM die stack in accordance with some embodiments of the present disclosure.

FIG. 4 is a schematic diagram illustrating a cross-sectional view of an example of an MRAM die stack in accordance with some embodiments of the present disclosure.

FIG. 5 is a flowchart illustrating an example process for fabricating an MRAM die stack in accordance with some embodiments of the present disclosure.

FIG. 6 is a schematic diagram illustrating a High-Performance Computing (HPC) system incorporating MRAM stacks in accordance with some embodiments of the present disclosure.

FIG. 7 is a schematic diagram illustrating an HPC system incorporating MRAM stacks and dynamic random-access memory (DRAM) stacks in accordance with some embodiments of the present disclosure.

FIG. 8 is a schematic diagram illustrating an HPC system incorporating MRAM stacks and flash memory stacks in accordance with some embodiments of the present disclosure.

FIG. 9 is a schematic diagram illustrating an HPC system incorporating MRAM stacks, DRAM stacks, and flash memory stacks in accordance with some embodiments of the present disclosure.

FIG. 10 is a schematic diagram illustrating an HPC system incorporating MRAM stacks, DRAM stacks, flash memory stacks, and RRAM stacks in accordance with some embodiments of the present disclosure.

### DETAILED DESCRIPTION

Aspects of the disclosure provide computing systems incorporating high-bandwidth MRAM stacks. Magneto-Resistive Random Access Memory (MRAM) is a type of current-controlled memory device utilizing a magnetic tunnel junction (MTJ) structure. An MTJ typically comprises two ferromagnetic layers separated by a thin insulating barrier layer. The MTJ includes a pinned layer, characterized by a magnetic orientation that remains substantially fixed during device operation, and a free layer, characterized by a magnetic orientation that is switchable via applied current. The free layer can change its magnetic orientation to store data (0 or 1). The insulating barrier layer, often comprising an oxide material, is disposed between the pinned layer and the free layer. The electrical resistance state of the MRAM device is determined by the relative magnetic orientation between the free layer and the pinned layer. A high resistance state corresponds to an anti-parallel alignment of the magnetic orientations of the free and pinned layers. Conversely, a low resistance state corresponds to a parallel alignment of the magnetic orientations of the free and pinned layers. Since MRAM does not require a power supply to retain its magnetic state, MRAM is a non-volatile memory that stores data even when power is off.

A computing system may include a central processing unit (CPU), a memory unit, interconnections between the memory and the CPU, and input and output (I/O) devices. The data movement between the memory and CPU may often limit the performance of the computing system (referred to as the von Neumann bottleneck) as the CPU has to wait for the memory unit or the I/O unit to transfer data. A significant amount of time and energy may be spent on data movement. To overcome the von Neumann bottleneck, high-bandwidth or stacked memory may be used, where multiple layers of memory chips are vertically stacked on top of each other and then connected with each other before connecting them to the logic chip. A high-performance computing (HPC) system with MRAM stacks may be used for non-volatile memory or in-memory computing applications. In some embodiments, a computing system may include a processing die and an MRAM stack connected to an interposer. In some embodiments, the interposer may be connected to a packaging substrate. The processing die may include a central processing unit (CPU), a graphics processing unit (GPU), an application-specific integrated circuit (ASIC), etc. for performing machine learning operations (e.g., training, inference, etc.). The MRAM stack may include a plurality of vertically stacked MRAM dies for performing memory (non-volatile) and computing operations. Each of the MRAM dies may include one or more crossbar arrays comprising MRAM devices for performing non-volatile memory and/or in-memory computing.

In some embodiments, the MRAM dies may implement a neural network, such as a convolutional neural network (CNN), a recurrent neural network (RNN), or a deep neural network (DNN), where a first MRAM die (e.g., the uppermost MRAM die) receives inputs to be processed by the neural network and another MRAM die (e.g., the bottommost MRAM die) produces analog outputs representing outputs of the neural network. The MRAM dies may be stacked on a logic die that may convert the analog outputs from the MRAM dies into digital signals, process these digitized signals, and provide inputs for the processing die via through-silicon vias (TSVs) and/or a physical layer (PHY) interface. The logic die and the processing die may be connected to the interposer through respective physical layer interface (PHY) blocks.

The computing system architecture disclosed herein may significantly reduce the data travel distance between the memory and the processor, which in turn lowers latency and diminishes processing loads on both the logic die and the processing die. MRAM devices exhibit non-volatility, retaining stored data without requiring continuous power, distinguishing them from volatile memory types such as Dynamic Random Access Memory (DRAM) and Static Random Access Memory (SRAM). Additionally, MRAM can offer substantially symmetrical read and write speeds. Furthermore, write operations in MRAM are generally nondestructive, enabling a high number of write cycles and consequently achieving high endurance, often characterized as effectively unlimited. Moreover, they may offer higher bandwidth, faster data transfer rates, and a wider memory interface.

The computing systems described herein may be used to implement edge AI (artificial intelligence), which refers to the deployment of artificial intelligence algorithms and data processing directly on edge devices or end devices (e.g., smartphones, sensors, or autonomous vehicles) rather than in remote cloud servers, thereby further reducing latency by processing data locally. The computing systems described herein are highly power-efficient, operating at low power and featuring low standby power due to their non-volatile memory design, resulting in lower hardware and operational costs, while enhancing data security by processing data locally and thus protecting users'sensitive and/or confidential information from network-based vulnerabilities. The computing systems can function offline, ensuring continued operation even during network outages or intermittent connectivity. Additionally, they may further enable improved model accuracy, as machine-learning models can be continuously refined and become more accurate with training on increasing volumes of data.

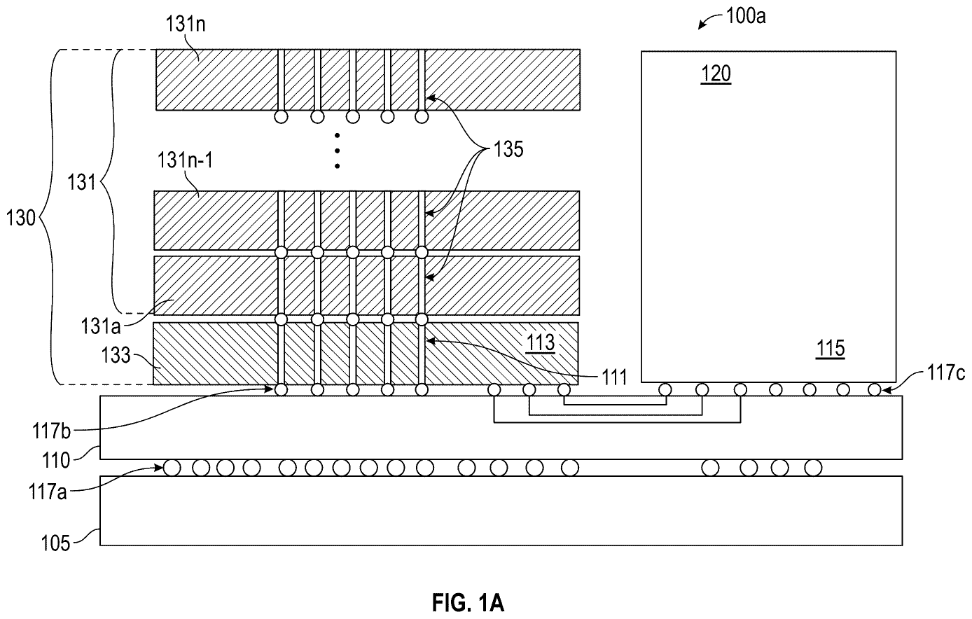

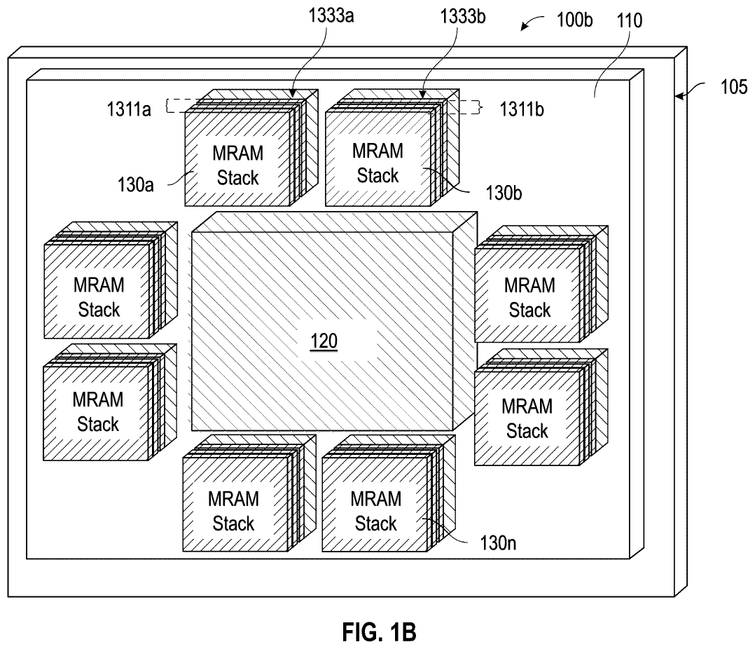

FIGS. 1A and 1B are schematic diagrams illustrating a side view and a top view of an example computing system for performing machine learning in accordance with some embodiments of the present disclosure.

As shown in FIG. 1A, computing system 100a may include a processing die 120 and a MRAM stack 130 connected to and mounted on an interposer 110. MRAM stack 130 may be connected to interposer 110 through TSVs (through-silicon vias) 111 and/or a physical (PHY) block 113 (also referred to as “the first PHY block”). Processing die 120 may be connected to interposer 110 through a physical (PHY) block 115 (also referred to as the “second PHY block”).

The PHY (physical layer interface) blocks 113 and 115 may function as a physical interface circuitry configured to handle the electrical signaling between MRAM stack 130 and processing die 120. PHY blocks 113 and 115 may ensure proper data transmission and reception between the different dies by managing signal timing, voltage levels, and other physical layer aspects.

Interposer 110 may be connected to a packaging substrate 105 through bump 117a. MRAM stack 130, TSVs 111, and PHY block 113 may further be electrically and mechanically connected to interposer 110 through micro-bumps 117b. Processing die 120 and block 115 may be further connected to interposer 110 through micro-bumps 117c. Micro-bumps 117a and 117b may include conductive materials (e.g., tin-based solder alloys to connect copper pillars). Micro-bumps 117a, 117b, and 117c may function as die-to-die interconnects providing electrical connectivity and mechanical stability between the MRAM stack 130, processing die 120, and interposer 110, enabling high-speed and low-latency data transmission within the computing system.

Interposer 110 may be a silicon substrate, which contains dense interconnection lines to ensure high-bandwidth and low-latency data transmission. The silicon interposer is configured to provide a sufficient surface area for mounting and interconnecting the dies. This design may enable high-speed, low-latency communication and data transfer between processing die 120 and MRAM stack 130 by providing dedicated interconnect pathways that efficiently route signals and power. It may also allow for finer-pitch connections between the dies compared to a standard package substrate (not shown in FIG. 1A).

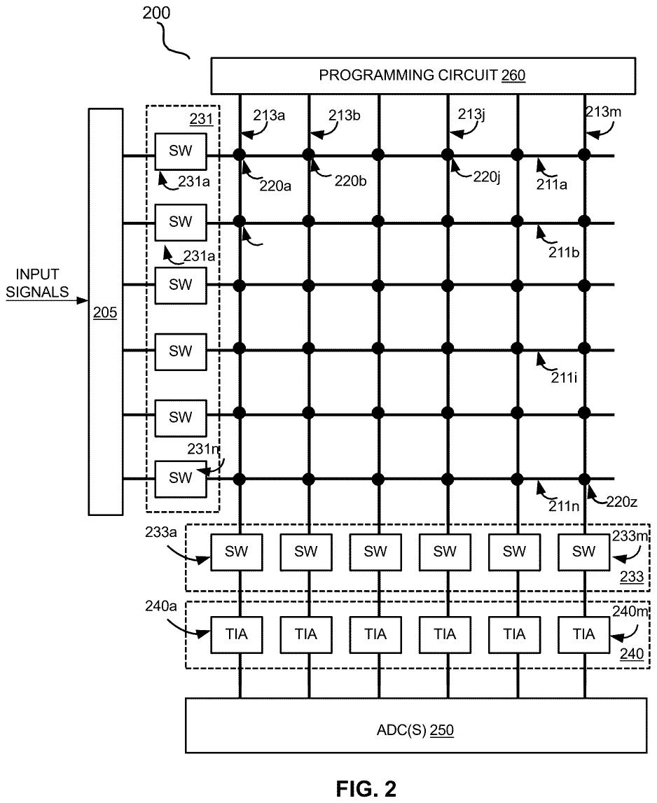

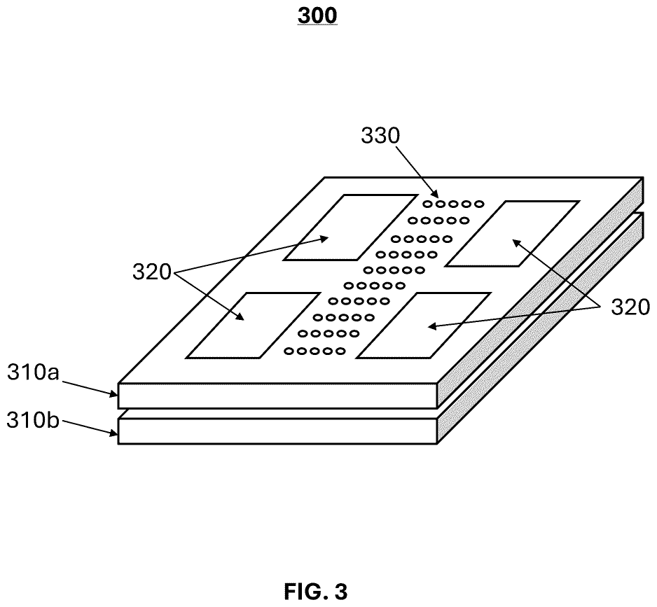

MRAM stack 130 may include multiple MRAM dies 131a, . . . , 131n (collectively referred to as the “MRAM dies 131”) and one or more logic dies 133. As shown, MRAM dies 131 may be vertically stacked on logic die 133. Each MRAM die 131a, . . . , 131n may include one or more crossbar arrays that may perform both memory (non-volatile) and computing functions. Each of the crossbar arrays may include a plurality of interconnecting electrically conductive wires (e.g., row wires, column wires, etc.), integrated circuits, and cross-point devices fabricated at the intersections of the electrically conductive wires configured to perform parallel analog multiplication and summation operations. The cross-point devices may include, for example, MRAM devices, resistive random-access memory devices, phase-change memory devices, floating gates, spintronic devices, and/or any other suitable devices with programmable resistance. In some embodiments, each of the cross-point devices in a MRAM die 131a, . . . , 131n may include one or more MRAM devices. For example, each MRAM die 131a, . . . , 131n may include one or more crossbar arrays as described in connection with FIGS. 2-3 below.

As an example, a crossbar array may receive an input voltage signal V and may produce an output current signal I. The relationship between the input voltage signal and the output current signal may be represented as I=VG, wherein G represents the conductance values of the cross-point devices. As such, the input signal may be weighted at each of the cross-point devices by its conductance value according to Ohm's law. The weighted currents output via each bit line may be accumulated according to Kirchhoff's current law. The conductance values of the cross-point devices may be programmed to values and/or weights representative of one or more matrices used for implementing a neural network or a portion of the neural network. Since MRAM is a binary device, each device can store one bit of data or weight (a “0” or “1”). MRAM may be directly utilized in binary neural networks for single-bit in-memory computing applications, where each device represents a one-bit weight and/or one-bit data. Furthermore, in implementations requiring higher precision, such as multi-bit neural networks, a group of MRAM devices can collectively store a multi-bit weight and/or multi-bit data for multi-bit in-memory computations. One or more of the cross-point devices may include one or more MRAM devices. Each of the MRAM devices may be programmed to a resistance state representative of a binary bit (i.e., a bit “0” or a bit “1”). In one implementation, a cross-point device may include a single MRAM device that may be programmed to store a single bit representing a single-bit weight or single-bit data. In another implementation, a group of cross-point devices may include multiple MRAM devices. Each of the MRAM devices may be programmed to store a binary bit. The combination of the binary bits stored in the MRAM devices of the cross-point devices may represent a multi-bit weight and/or multi-bit data. The crossbar array may produce analog output signals (e.g., current signals) representing the processing results of the input voltage signal by the matrix.

In some embodiments, MRAM dies 131 may implement a neural network that executes machine learning algorithms. The neural network may include multiple convolutional layers, each of which may perform certain convolution operations (e.g., 2D convolution, depth-wise convolution, etc.). Each layer of the neural network may be implemented using one or more crossbar arrays. For example, one or more first crossbar arrays may implement a first layer (e.g., an input layer) of the neural network. The first crossbar array(s) may receive an analog input and perform one or more convolution operations on the analog input. In some embodiments, the analog input may correspond to analog sensing signals produced by one or more sensors, such as image sensors, audio sensors, infrared sensors, thermal sensors, LiDAR sensors, radar sensors, inertial sensors, etc. Performing a convolution operation on the analog sensing data may involve applying one or more kernels to different portions of the analog input. For example, a 2D convolution may be performed by applying a single convolution kernel to the analog input. More particularly, the convolution kernel may be used to scan each part of the analog input with the same size as the convolution kernel to produce a convolution result. As another example, performing a depth-wise convolution on the sensing data may involve convolving each channel of the analog input with a respective kernel and stacking the convolved outputs together. For example, the conductance values of a plurality of cross-point devices in the first crossbar array(s) may be programmed to values that represent a 2D convolution kernel. The first crossbar array(s) may output a current signal representing a convolution of the analog input and the 2D convolution kernel. In some embodiments, the crossbar array(s) may store multiple 2D convolution kernels by mapping each of the 2D convolution kernels to a plurality of cross-point devices of the first crossbar array(s). The first crossbar array(s) may output a plurality of output signals (e.g., current signals) representative of the convolution results. The outputs of the first crossbar array(s) may be provided as inputs to one or more second crossbar arrays implementing a subsequent neural network layer for further processing. The outputs of the second crossbar arrays may be provided as inputs to additional crossbar arrays implementing subsequent neural network layers (e.g., additional hidden layers) for further processing. The outputs of the second crossbar arrays may be provided to one or more crossbar arrays implementing a subsequent layer of the neural network (e.g., a second hidden layer) for processing. One or more third crossbar arrays may implement an output layer of the neural network. The outputs of the third crossbar arrays (e.g., analog current signals) may represent the output of the neural network. In some embodiments, the topmost MRAM die (e.g., MRAM die 131n) may receive the analog input representing signals to be processed by the neural network and implement the input layer of the neural network. The bottommost MRAM die (e.g., MRAM die 131a) may produce an analog output representing the output of the neural network (i.e., the result of processing the analog input). In some embodiments, the crossbar arrays may implement a deep neural network (DNN) configured to execute machine learning algorithms.

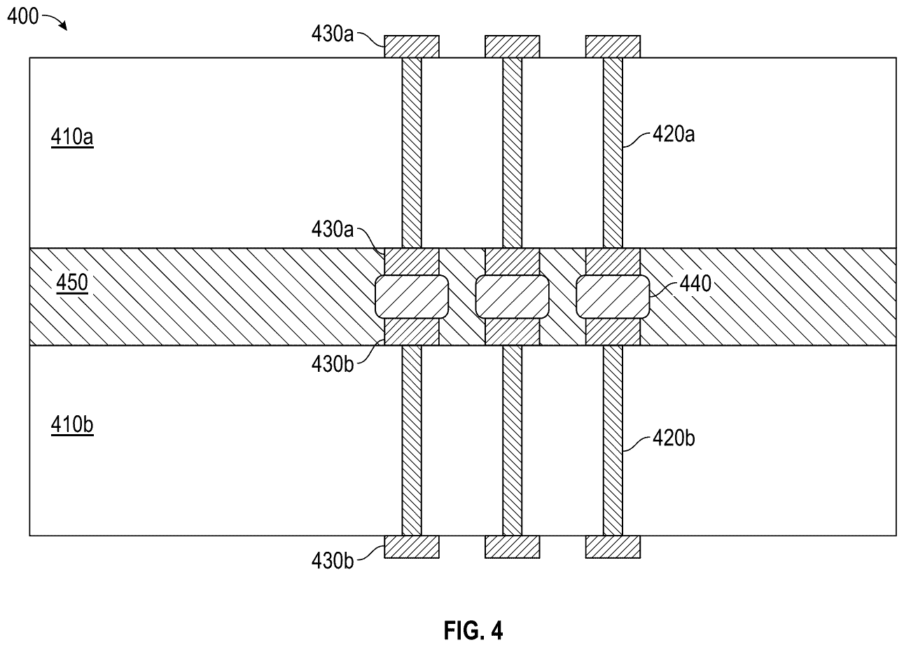

The vertically stacked MRAM dies 131 may be connected through interconnects 135. Interconnects 135 may include TSVs, micro-bumps (e.g., solder bumps) connecting TSVs between adjacent MRAM dies, etc. that may create physical and electrical connections between adjacent MRAM dies. Interconnects 135 may enable fast vertical data transmission through MRAM dies 131 and MRAM stack 130. In some embodiments, adjacent MRAM dies 131 may be interconnected as described in connection with FIG. 4 below.

Logic die 133 may contain logic circuitry configured to control and manage MRAM dies 131 and function as an interface between processing die 120 and MRAM dies 131. For example, logic die 133 may handle memory requests, data transfers, and other control functions for MRAM stack 130. In some embodiments, logic die 133 may include analog-to-digital converter (ADC) circuits that may convert the analog output produced by MRAM dies 131 into digital signals, process the digital signals, and/or provide the digital signals to processing die 120 through TSVs and/or PHY blocks.

Processing die 120 may include one or more central processing units (CPUs), graphics processing units (GPUs), system-on-chip (SoC) devices, application-specific integrated circuits (ASICs) designed for specialized and efficient processing, and/or other suitable hardware processors and/or circuitry that may perform machine-learning operations (e.g., training machine learning models and/or performing inference using trained machine learning models). For example, processing die 120 may generate a predictive output by running a trained machine-learning model using the output provided by MRAM dies 131. The predictive output may represent, for example, a classification result (e.g., a class label assigned to the sensing data), a decision derived from the machine-learning model, or a natural-language response generated by a large language model (LLM). The machine-learning model may refer to a model artifact created by processing die 120 using training data that includes known training inputs and corresponding known outputs (e.g., correct answers associated with respective training inputs). Processing die 120 may identify patterns in the training data that map the known inputs to the known outputs (the outputs to be predicted), thereby producing a machine-learning model capable of capturing these patterns for various tasks, including traditional classification and advanced natural-language understanding and generation.

The machine-learning models may include models composed of a single level of linear or non-linear operations (e.g., support vector machines), neural networks composed of multiple levels of non-linear operations, and advanced transformer-based architecture designed for processing sequential data. The neural network may include an input layer, one or more hidden layers, and an output layer. The neural network may be trained, for example, by adjusting the weights in accordance with a backpropagation learning algorithm or similar techniques. As an example, the machine learning models may include transformer-based LLMs. An LLM architecture may include an embedding layer configured to convert input tokens into vector representations, which are subsequently combined with positional encodings to capture the order of tokens. The LLM architecture may further include multiple transformer blocks, each integrating multi-head self-attention mechanisms with residual connections and layer normalization, along with feed-forward networks. An output softmax layer may generate a probability distribution over tokens for prediction.

Referring to FIG. 1B, computing system 100b illustrates a top view of computing system 100a. Computing system 100b may include processing die 120 and a plurality of MRAM stacks 130a, 130b, . . . , 130n fabricated on interposer 110 and mounted on a packaging substrate 105. Each of MRAM stacks 130a, 130b, . . . , 130n may include an MRAM stack 130 described in connection with FIG. 1A above. For example, a first MRAM stack 130a may include a first plurality of MRAM dies 1311a vertically stacked on a first logic die 1333a. A second MRAM stack 130b may include a second plurality of MRAM dies 1311b stacked on a second logic die 1333b. The first plurality of MRAM dies 1311a and the second plurality of MRAM dies 1311b may include MRAM dies 131a-131n as described in connection with FIG. 1A. The first logic die 1333a and the second logic die 1333b may be the logic die 133 as described in connection with FIG. 1A.

MRAM stacks 130a, 130b, . . . , 130n may each include vertically stacked MRAM dies that may perform non-volatile memory operations, ensuring data retention even when power is removed. The MRAM stacks may operate in an analog mode, enabling specialized computations. Their in-memory computing functionality reduces data movement and enhances performance. Furthermore, these stacks facilitate multilayer neural network processing by supporting parallel processing, making them well-suited for complex AI workloads. They also combine low-power operation with fast data transfer and rapid response times, leading to increased throughput and overall efficiency.

FIG. 2 is a diagram illustrating an example 200 of a crossbar array in accordance with some embodiments of the present disclosure. As shown, crossbar array 200 may include a plurality of interconnecting electrically conductive wires, such as one or more row wires 211a, 211b, . . . , 211i, . . . , 211n, and column wires 213a, 213b, . . . , 213j, . . . , 213m for an n-row by m-column crossbar array. The crossbar array 200 may further include cross-point devices 220a, 220b, . . . , 220z, etc. Each of the cross-point devices may connect to a row wire and a column wire. For example, cross-point device 220a may be connected a first row wire 211a and a first column wire 213a. Cross-point device 220b may be connected to the first row wire 211a and a second column wire 213b. Cross-point device 220j may be connected to the first row wire 211a and the jth column wire 213j. The number of the column wires 213a-m and the number of the row wires 211a-n may or may not be the same. Crossbar array 200 may further include a word line (WL) logic 205 that is connected to the cross-point devices via the row wires 211a-n. The WL logic 205 may include any suitable component for applying input signals to selected cross-point devices via row wires 211a-n, such as one or more digital-to-analog converters (DACs), amplifiers, etc. Each of the input signals may be a voltage signal, a current signal, etc. The input signals may correspond to the analog sensing signals produced by various sensors (not shown).

Row wires 211a-n may include a first row wire 211a, a second row wire 211b, . . . , 211i, . . . , and an n-th row wire 211n. Each of row wires 211a, . . . , 211n may be and/or include any suitable electrically conductive material. In some embodiments, each row wire 211a-n may be a metal wire.

Column wires 213a-m may include a first column wire 213a, a second column wire 213b, . . . , and an m-th column wire 213m. Each column wire 213a-m may be and/or include any suitable electrically conductive material. In some embodiments, each column wire 213a-m may be a metal wire.

Each cross-point device 220 may be and/or include any suitable device with tunable resistance, such as a memristor, phase-change memory (PCM) devices, floating gates, spintronic devices, ferroelectric devices, MRAM devices, etc.

In some embodiments, one or more cross-point devices 220 may include an MRAM device and may be configured to store a weight (e.g., a single-bit weight or a multi-bit weight) and/or a data item (e.g., single-bit data or multi-bit data). Due to the inherent binary nature of typical MRAM devices, such a cross-point device 220 may implement a binary cell and can be used for applications that operate on binary values (e.g., binary neural networks). In some embodiments, multiple cross-point devices 220 may be configured to store a multi-bit weight for performing multi-bit operations, such as multi-bit in-memory computing. More particularly, for example, each of the cross-point devices includes an MRAM device. Each of the MRAM devices may store a binary bit (i.e., a bit “0” or a bit “1”), and a group of MRAM devices may store a multi-bit weight. A combination of the stored binary bits may be converted into a multi-bit value representing a weight of multiple bits (also referred to as a multi-bit weight). Any suitable encoding scheme may be used to convert the combination of binary bits into a corresponding multi-bit weight value, such as binary-weighted encoding, thermometer encoding, etc. Different combinations of the binary bits stored in the multiple MRAM devices of multiple cross-point devices may represent different values of the weight. In some embodiments, a group of cross-point devices connected to the same row wire and a plurality of different column wires may store a multi-bit weight. For example, a first MRAM device of a first cross-point device (e.g., cross-point device 220a) may be programmed to a first resistance state (e.g., HRS or LRS) representative of a first bit of the multi-bit weight (“0” or “1”). A second MRAM device of a second cross-point device (e.g., cross-point device 220b) may be programmed to a second resistance state (e.g., HRS or LRS) representative of a second bit (“0” or “1”) of the multi-bit weight. The jth MRAM device of the nth cross-point device (e.g., cross-point device 220j) may be programmed to a resistance state (e.g., HRS or LRS) representative of the jth bit (“0” or “1”) of the multi-bit weight. A group of a suitable number of cross-point devices (e.g., j cross-point devices) may be programmed to store a multi-bit weight (e.g., a weight of j bits). Using multiple MRAM devices to implement multiple cross-point devices may enable storing a wider range of weight values compared to just using a single binary cell. Each of row wires 211a-n may be connected to one or more row switches 231 (e.g., row switches 231a-231n). Each row switch 231 may include any suitable circuit structure that may control the current flowing through row wires 211a-211n. For example, row switches 231 may be and/or include a CMOS switch circuit.

Each of column wires 213a-m may be connected to one or more column switches 233 (e.g., switches 233a-233m). Each column switch 233a-233m may include any suitable circuit structure that may control the current that passes through column wires 213a-213m. For example, column switches 233a-233m may be and/or include a CMOS switch circuit. In some embodiments, one or more of switches 231a-231n and 233a-233m may further provide fault protection, electrostatic discharge (ESD) protection, noise reduction, and/or any other suitable function for one or more portions of crossbar array 200.

The programming circuit 260 may program the cross-point devices 220 selected by switches 231 and/or 233 to suitable conductance values. For example, programming a cross-point device that includes an MRAM device may involve applying a suitable programming signal across the MRAM device to alter the magnetic orientation of the free layer relative to the pinned layer within the magnetic tunnel junction (MTJ) of the MRAM device. The programming signal may be, for example, an electrical current of appropriate magnitude and polarity. The electrical resistance of each MRAM device in the cross-point device may thereby be switched between a high-resistance state (HRS) and a low-resistance state (LRS). The HRS and LRS may correspond to an anti-parallel and a parallel magnetic alignment, respectively. For instance, a “set” operation may involve applying a first programming signal to switch the MRAM device from the HRS to the LRS (e.g., inducing parallel alignment). Conversely, a “reset” operation may involve applying a second programming signal (e.g., with opposite current polarity or a different magnitude) to switch the MRAM device from the LRS back to the HRS (e.g., inducing anti-parallel alignment).

The output sensor(s) 240 may include any suitable component for converting the current flowing through column wires 213a-m into the output signal, such as one or more TIAs (trans-impedance amplifiers) 240a-m. Each TIA 240a-m may convert the current through a respective column wire into a respective voltage signal. One or more ADCs 250 may convert the voltage signal produced by TIA 240a-m into a digital output. In some embodiments, output sensor(s) 240 may further include one or more multiplexers (not shown).

Crossbar array 200 may perform parallel weighted voltage multiplication and current summation. For example, an input voltage signal may be applied to one or more rows of crossbar array 200 (e.g., one or more selected rows). The input signal may flow through the cross-point devices of the rows of the crossbar array 200. The cross-point devices may include a plurality of MRAM devices. Each of the MRAM devices may be programmed to a particular resistance state (e.g., HRS or LRS) representative of a binary bit (e.g., a bit “0” or a bit “1”). In some embodiments in which crossbar array 200 implements a single-bit neural network, a single MRAM device may be programmed to a resistance state representative of a single bit weight and can store a binary weight of the single-bit neural network. In some embodiments in which crossbar array 200 implements a multi-bit neural network, multiple MRAM devices may be used to store a multi-bit weight. In particular, each of the MRAM devices may be programmed to store a single binary bit (i.e., a bit “0” or a bit “1”). A combination of the stored binary bits may be encoded as a multi-bit value representing the multi-bit weight using a predefined encoding scheme. Different combinations of the binary bits stored in the MRAM devices may represent different values of the weight. This configuration enables the storage of a multi-bit weight value with multiple MRAM devices, where the specific pattern of programmed states across the constituent MRAM devices determines the overall weight value. By Ohm's law, the input voltage multiplies the cross-point conductance and generates a current from the cross-point device. By Kirchhoff's law, the summation of the current passing through the devices on each column generates the current as the output signal, which may be read from the columns (e.g., outputs of the ADCs). According to Ohm's law and Kirchhoff's current law, the input-output relationship of the crossbar array can be represented as I=VG, wherein I represents the output signal matrix as current; V represents the input signal matrix as voltage; and G represents the conductance matrix of the cross-point devices. As such, the input signal is weighted at each of the cross-point devices by its conductance according to Ohm's law. The weighted current is output via each column wire and may be accumulated according to Kirchhoff's current law. Thus, the conductance G of each cross-point device, which represents the stored weight (a single-bit weight or a multi-bit weight), determines the current generated according to Ohm's Law. In some embodiments in which single-bit weights are stored in multiple MRAM devices the conductance directly corresponds to the state of a single MRAM device. In some embodiments in which multi-bit weights are stored across multiple MRAM devices, their combined programmed state may be decoded to determine the effective conductance G corresponding to the intended multi-bit value. This may enable in-memory computing (IMC) via parallel multiplications and summations performed in the crossbar arrays.

Crossbar array 200 may be configured to perform vector-matrix multiplication (VMM). A VMM operation may be represented as Y=XA, wherein each of Y, X, A represents a respective matrix. More particularly, for example, input vector X may be mapped to the input voltage V of crossbar array 200. Matrix A may be mapped to conductance values G. The output current I may be read and mapped back to output results Y. In some embodiments, crossbar array 200 may be configured to implement a portion of a neural network by performing VMMs.

In some embodiments, crossbar array 200 may perform convolution operations. For example, performing 2D convolution on input data may involve applying a single convolution kernel to the input signals. Performing a depth-wise convolution on the input data may involve convolving each channel of the input data with a respective kernel corresponding to the channel and stacking the convolved outputs together. The convolution kernel may have a particular size defined by multiple dimensions (e.g., a width, a height, a channel, etc.). The convolution kernel may be applied to a portion of the input data having the same size to produce an output. The output may be mapped to an element of the convolution result that is located at a position corresponding to the position of the portion of the input data.

The programming circuit 260 may program the crossbar array 200 to store convolution kernels for performing 2D convolution operations. For example, a convolution kernel may be converted into a vector and mapped to a plurality of cross-point devices of the crossbar array that are connected to a given bit line. In particular, the conductance values of the cross-point devices may be programmed to values representative of the convolution kernel. In response to the input signals, the crossbar array 200 may output, via the given bit line, a current signal representative of a convolution of the input signals and the 2D convolution kernel. In some embodiments, crossbar array 200 may store multiple 2D convolution kernels by mapping each of the 2D convolution kernels to the cross-point devices connected to a respective bit line. Crossbar array 200 may output a plurality of output signals (e.g., current signals) representative of the convolution results via column wires 213.

For a binary neural network, the output sensor(s) 240 may directly read the output from the binary neural network. For example, each TIA 240a-m can sense the cumulative analog current flowing through its corresponding column wire (213a-m). This current represents the sum of the weighted input signals (e.g., voltage multiplied by MRAM conductance) from the activated row(s) connected to that specific column, representing one element of the output vector computed via the crossbar's multiply-accumulate function. The TIA may generate a voltage output representing the resulting analog signal. The voltage output of the TIA may be converted into a digital output by one or more ADCs 250.

For a multi-bit neural network, multiple MRAM devices on the same row wire (e.g., multiple cross-point devices connected to a first word line, such as 211a, 211b, . . . , 211n) are used to store a multi-bit weight, with each MRAM device storing one bit of the multi-bit weight. The output sensor(s) 240 may include specialized circuitry (not shown) for the multi-bit applications and TIA circuits. For example, the specialized circuitry may include reading circuitry, decoding circuitry, summation circuitry, etc. configured to read, decode, and combine the current signals from the column wires connected to the MRAM devices (e.g., column wires 213a, 213b, . . . , 213m) to generate the output of the multi-bit neural network. For example, to implement a 2-bit neural network, two MRAM devices connected to the same row wire and two different column wires (e.g., MRAM devices 220a and 220b, MRAM devices 220c and 220d, etc.) may be used to store a 2-bit weight. Generating the final output of the 2-bit neural network may involve measuring the current signals from the column wires connected to the MRAM devices using the TIAs 240a-m connected to the column wires. The conductance from each of the column wires connected to the group of MRAM devices may be measured, combined, and/or decoded using the special circuitry (not shown) according to the selected encoding scheme to produce the final multi-bit value as an output. The summation circuit may include, for example, an operational amplifier configured to perform weighted summing according to the encoding scheme, current mirrors, etc. The output of the summation circuit may be provided to ADC(s) 250 to generate a digital output.

FIG. 3 is a schematic diagram illustrating a perspective view of an example MRAM die stack 300 in accordance with some embodiments of the present disclosure.

As shown, MRAM die stack 300 may include MRAM dies 310a and 310b vertically stacked and interconnected by interconnects 330. Interconnects 330 may include TSVs, micro-bumps, and any other suitable vertical electrical interconnects that pass through the first MRAM die 310a and the second MRAM die 310b. Each of the MRAM dies 310a and 310b may include one or more arrays of MRAM devices. For example, one or more crossbar arrays 320 may be fabricated on the MRAM die 310a. Each of the crossbar arrays 320 may be and/or include a crossbar array 200 as described in connection with FIG. 2. The MRAM dies 310a and 310b may correspond to two adjacent MRAM dies 131 as described in connection with FIG. 1A. Interconnects 330 may correspond to interconnects 135 as described in connection with FIG. 1A.

FIG. 4 is a schematic diagram illustrating a cross-sectional view of an example 400 of an MRAM die stack in accordance with some embodiments of the present disclosure.

As shown, MRAM die stack 400 may include a first MRAM wafer 410a and a second MRAM wafer 410b vertically stacked and connected through TSVs 420a-420b, micro-pads 430a-430b, and solder micro-bumps 440. Each of the first MRAM wafer 410a and the second MRAM wafer 410b may include MRAM arrays and supporting circuitry. First MRAM wafer 410a and second MRAM wafer 410b may be mechanically coupled and protected by die underfill 450, which fills the gap between the wafers surrounding the micro-pads 430a-430b and solder micro-bumps 440 to enhance structural integrity and mitigate thermo-mechanical stress.

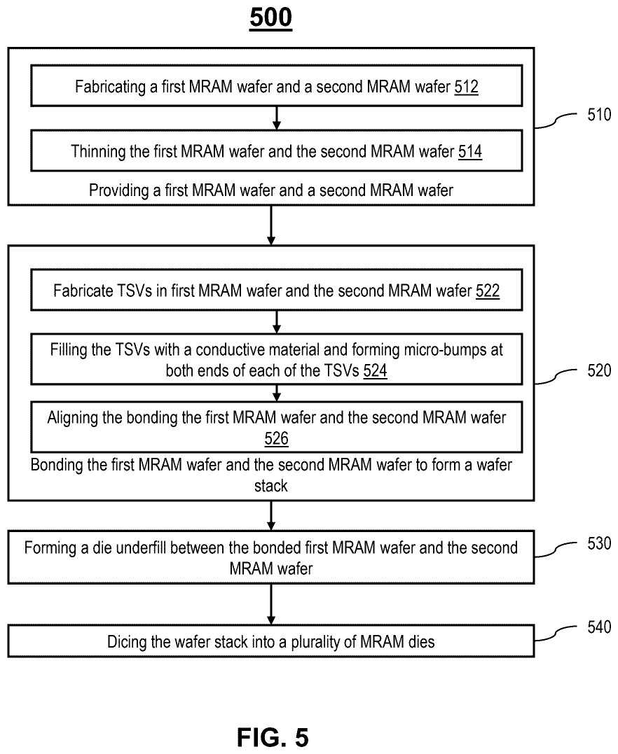

FIG. 5 is a flowchart illustrating an example process 500 for fabricating an MRAM die stack in accordance with some embodiments of the present disclosure. Process 500 may be carried out to fabricate MRAM die stack 400 as described in connection with FIG. 4.

At 510, a first MRAM wafer and a second MRAM wafer may be provided. For example, at 512, the first MRAM wafer and the second MRAM wafer may be fabricated. The first MRAM wafer and the second MRAM wafer may include MRAM arrays and supporting circuitry. At 514, the first MRAM wafer and the second MRAM wafer may be thinned from the backside to a suitable thickness (e.g., a thickness of less than 100 μm). In some embodiments, the thickness of the thinned first MRAM wafer and/or the thinned second MRAM wafer (e.g., MRAM wafers 410 a and 410 b of FIG. 4) may be around 40 to 60 μm.

At 520, the first MRAM wafer may be bonded to the second MRAM wafer to form a wafer stack. For example, at 522, through-silicon vias (TSVs) (e.g., TSVs 420a-420b of FIG. 4) may be fabricated in the first MRAM wafer and the second MRAM wafer. At 524, the TSVs may be filled with a conductive material (e.g., copper). In some embodiments, an insulating layer may be applied to the via sidewalls, and the conductive material may be deposited or electroplated to fill these vias, creating conductive vertical connections. Micro-pads (e.g., micro-pads 430a-430b) may be formed at both ends (on the top and bottom surfaces) of each of the TSVs. The micro-pads may include one or more conductive materials, such as copper, tin, etc. The micro-pads may be formed using deposition and patterning techniques such as electroplating or deposition onto the ends of the TSVs. At 526, the first MRAM wafer and the second MRAM wafer may then be aligned and bonded to each other, for example, using solder (e.g., solder 440 of FIG. 4) to form the wafer stack 400 as shown in FIG. 4. The solder may form electrical and mechanical connections between the micro-pads.

At 530, a die underfill may be formed between the bonded MRAM wafers. For example, an underfill material (die underfill 450 of FIG. 4) may be injected between the bonded MRAM wafers to reinforce the solder joints, improve mechanical reliability, and enhance thermal performance. The underfill material may be an epoxy-based compound or another type of polymer that may provide suitable adhesion, mechanical strength, and thermal conductivity.

At 540, the wafer stack may be diced into a plurality of MRAM dies. In particular, the wafer stack may be precisely diced along predefined scribe lines. Each individual die, containing its own MRAM arrays, TSVs, micro-pads, and circuitry, may be ready for packaging and integration into larger electronic systems, such as the MRAM stack 130 of FIG. 1A.

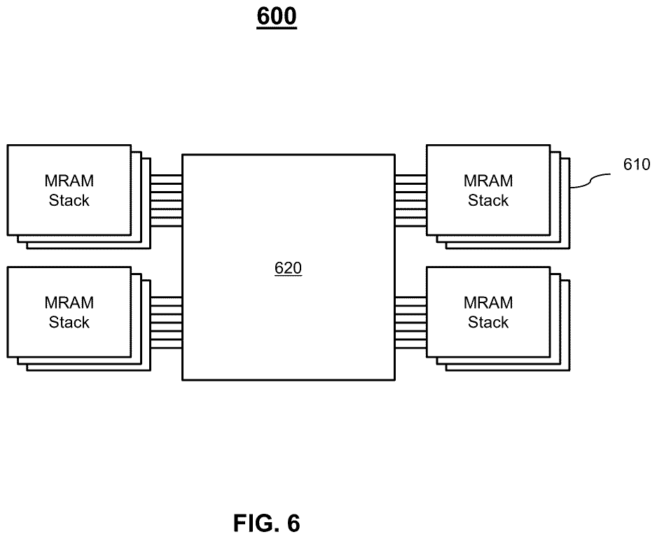

FIG. 6 illustrates a High-Performance Computing (HPC) system 600 using MRAM stacks to form high-bandwidth MRAM memory (HBRM). MRAM's non-volatility and its ability to store multi-bit weights via analog behavior allow it to be used for both memory and computation, thereby enabling massive parallel processing. Consequently, the MRAM stack is advantageous for multilayer neural network processing, offering low-power consumption, rapid data transfer, fast response times, high throughput, and enhanced overall efficiency.

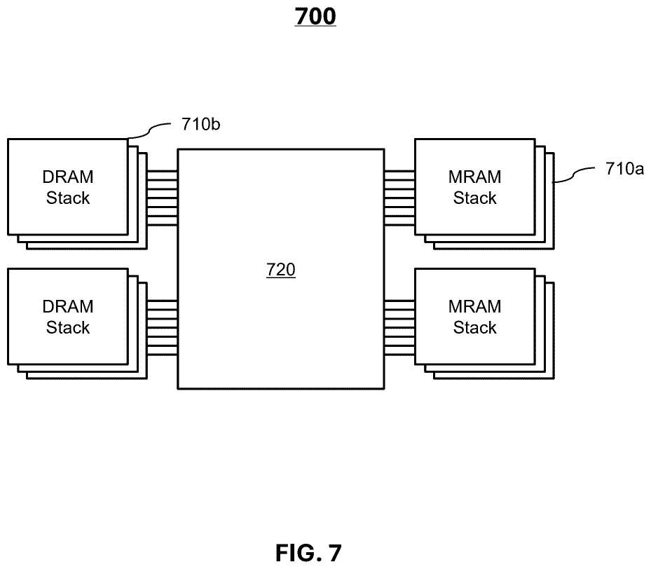

FIG. 7 is a schematic diagram illustrating a computing system 700 incorporating stacked MRAM dies and vertically stacked High Bandwidth Memory (HBM) dies in accordance with some embodiments of the present disclosure. As shown, computing system 700 may include one or more MRAM stacks 710a connected to a processing die 720. The processing die 720 may be the processing die 120 of FIG. 1. Each MRAM stack 710a may be the MRAM stack 130 of FIG. 1. System 700 may further include one or more DRAM stacks or HBM stacks 710b connected to the processing die 720. Each of the HBM stacks 710b may include stacked HBM dies. Each of the HBM dies may include DRAM devices. By leveraging stacked DRAM, HBM stacks 710b may offer low-latency processing for efficient handling of time-sensitive or data-intensive operations. By incorporating both MRAM dies and HBM dies, computing system 700 leverages the high-performance and energy-efficiency using HBM and MRAM stacks, making it especially suitable for edge applications demanding rapid response times from DRAM stack, and energy efficiency from MRAM stack, such as autonomous vehicles, robotics, and critical monitoring systems.

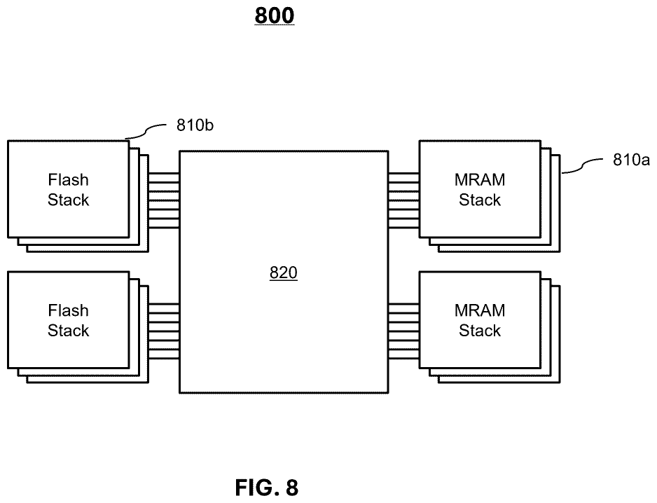

FIG. 8 is a schematic diagram illustrating a computing system 800 incorporating stacked MRAM dies and stacked flash memory. As shown, computing system 800 may include one or more MRAM stacks 810a connected to a processing die 820. The processing die 820 may be the processing die 120 of FIG. 1. Each of the MRAM stacks 810a may be the MRAM stack 130 of FIG. 1. The computing system 800 may further include one or more High-Bandwidth Flash (HBF) or Flash stacks 810b comprising vertically stacked HBF dies. Each of the HBF dies may include flash memory and supporting circuitry. The HBF dies may offer higher memory capacity at a relatively low cost, making them particularly well-suited for handling large volumes of data. The hybrid configuration comprising the MRAM stacks 810a and the HBF stacks 810b may enable computing system 800 to efficiently process large datasets, especially in edge applications where a large volume of data is required while the ultra-low latency is not the strictest requirement.

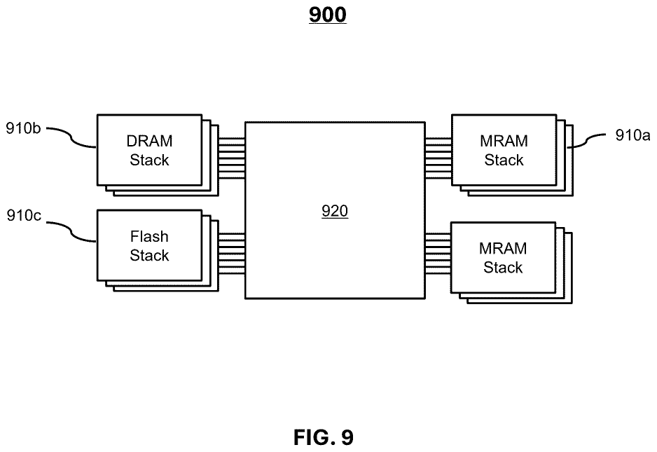

FIG. 9 is a schematic diagram illustrating a computing system 900 incorporating stacked MRAM dies, stacked HBM dies, and stacked HBF dies in accordance with some embodiments of the present disclosure. As shown, computing system 900 may include one or more MRAM stacks 910a connected to a processing die 920. The processing die 920 may be the processing die 120 of FIG. 1. Each of the MRAM stacks 910a may include an MRAM stack 130 of FIG. 1. Computing system 900 may further include one or more HBM stacks or DRAM stacks 910b connected to the processing die 920. Each of the HBM stacks 910b may include stacked HBM dies. The computing system 900 may further include one or more HBF stacks or flash stacks 910c, each comprising stacked HBF dies. The MRAM dies may be dedicated to in-memory computing and deep neural network processing as described above. Meanwhile, HBM dies may store more active data or weights requiring rapid access. HBF dies may store large-volume but less-active data or weights, providing a balanced approach that maximizes performance and cost-effectiveness.

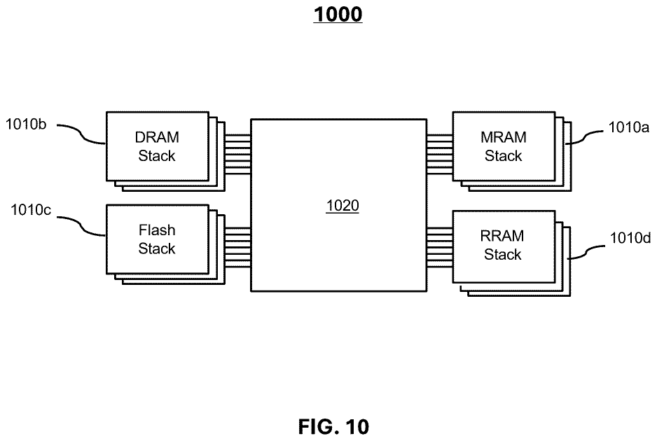

FIG. 10 is a schematic diagram illustrating a computing system 1000 incorporating stacked MRAM dies, stacked HBM dies, stacked HBF, and stacked RRAM dies in accordance with some embodiments of the present disclosure. As shown, computing system 1000 may include one or more MRAM stacks 1010a connected to a processing die 1020. The processing die 1020 may be the processing die 120 of FIG. 1. Each of the MRAM stacks 1010a may include an MRAM stack 130 of FIG. 1. Computing system 1000 may further include one or more HBM stacks or DRAM stacks 1010b connected to the processing die 1020. Each of the HBM stacks 1010b may include stacked HBM dies. The computing system 1000 may further include one or more HBF stacks or flash stacks 1010c, each comprising stacked HBF dies. The computing system 1000 may further include one or more RRAM stacks 1010d, each comprising stacked RRAM dies. The MRAM dies may be dedicated to in-memory computing and deep neural network processing as described above. Meanwhile, HBM dies may store more active data or weights requiring rapid access. HBF dies may store large-volume but less-active data or weights, RRAM dies may perform multilevel memory and analog in-memory computing, providing a balanced approach that maximizes the computer system's performance and cost-effectiveness.

For simplicity of explanation, the methods of this disclosure are depicted and described as a series of acts. However, acts in accordance with this disclosure can occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events.

The terms “approximately,” “about,” and “substantially” as used herein may mean within a range of normal tolerance in the art, such as within 2 standard deviations of the mean, within ±20% of a target dimension in some embodiments, within ±10% of a target dimension in some embodiments, within ±5% of a target dimension in some embodiments, within ±2% of a target dimension in some embodiments, within ±1% of a target dimension in some embodiments, and yet within ±0.1% of a target dimension in some embodiments. The terms “approximately” and “about” may include the target dimension. Unless specifically stated or obvious from context, all numerical values described herein are modified by the term “about.”

As used herein, a range includes all the values within the range. For example, a range of 1 to 10 may include any number, combination of numbers, sub-range from the numbers of 1, 2, 3, 4, 5, 6, 7, 8, 9, and 10 and fractions thereof.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, the use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. A computing system, comprising:
a processing die connected to an interposer; and
a magneto-resistive random-access memory (MRAM) stack connected to the interposer, wherein the MRAM stack comprises:
a plurality of vertically stacked MRAM dies, wherein each of the plurality of vertically stacked MRAM dies comprises one or more crossbar arrays configured to perform at least one of non-volatile memory or in-memory computing, wherein each of the one or more crossbar arrays comprises a plurality of bit lines, a plurality of word lines, and a plurality of cross-point devices at intersections of the plurality of word lines and the plurality of bit lines, and wherein each of the cross-point devices comprises at least one MRAM device.

2. The computing system of claim 1, wherein the plurality of vertically stacked MRAM dies are configured to implement a neural network, wherein a first MRAM die of the plurality of vertically stacked MRAM dies receives an input analog signal, and wherein a second MRAM die of the plurality of vertically stacked MRAM dies produces an output analog signal representing a processing result of the input analog signal after being processed by the neural network.

3. The computing system of claim 2, wherein a cross-point device of the plurality of cross-point devices comprises an MRAM device configured to store a single-bit weight or single-bit data.

4. The computing system of claim 2, wherein the plurality of cross-point devices comprises a plurality of MRAM devices configured to store a multi-bit weight or multi-bit data, wherein each of the plurality of MRAM devices is configured to store a binary bit, and wherein a combination of a plurality of binary bits stored in the plurality of MRAM devices corresponds to the multi-bit weight or the multi-bit data.

5. The computing system of claim 2, wherein the plurality of vertically stacked MRAM dies is vertically stacked on a logic die, and wherein the logic die is connected to the interposer through a first physical layer block.

6. The computing system of claim 5, wherein the logic die is connected to the second MRAM die through a plurality of interconnects.

7. The computing system of claim 5, wherein the logic die comprises an analog-to-digital converter that converts the output analog signal into a digital signal.

8. The computing system of claim 7, wherein the analog-to-digital converter further provides the digital signal to the processing die through the first physical layer block.

9. The computing system of claim 5, wherein the processing die is connected to the interposer through a second physical layer block.

10. The computing system of claim 5, wherein the first MRAM die comprises a digital-to-analog converter.

11. The computing system of claim 1, wherein the processing die comprises at least one of a central processing unit, a graphics processing unit, or an application-specific integrated circuit for performing machine learning.

12. The computing system of claim 1, wherein adjacent MRAM dies of the plurality of MRAM dies are connected through a plurality of interconnects, wherein the plurality of interconnects comprises through-silicon vias (TSVs).

13. The computing system of claim 12, wherein the plurality of interconnects further comprises a plurality of micro-bumps.

14. The computing system of claim 1, further comprising a plurality of vertically stacked HBM (High-Bandwidth Memory) dies connected to the processing die, wherein each of the plurality of vertically stacked HBM dies comprises DRAM (dynamic random-access memory) devices, and wherein the HBM dies are configured to perform low-latency processing of time-sensitive or data-intensive operations.

15. The computing system of claim 14, further comprising a plurality of stacked HBF (High-Bandwidth Flash) dies, wherein each of the HBF dies comprises flash memory devices.

16. The computing system of claim 15, wherein the plurality of vertically stacked MRAM dies is configured to perform non-volatile memory, in-memory computing and deep neural network processing, wherein the plurality of stacked HBM dies are configured to store frequently accessed data or weights of a neural network, and wherein the plurality of stacked HBF dies are configured to store high volume less frequently accessed data or weights of the neural network.

17. The computing system of claim 1, further comprising a plurality of vertically stacked resistive random-access memory (RRAM) dies connected to the interposer.

18. A method, comprising:
bonding a first magneto-resistive random-access memory (MRAM) wafer and a second MRAM wafer to form a wafer stack, wherein each of the first MRAM wafer and the second MRAM wafer comprises one or more crossbar arrays configured to perform non-volatile memory, and in-memory computing operations, and wherein each of the one or more crossbar arrays comprises a plurality of bit lines, a plurality of word lines, and a plurality of MRAM devices at intersections of the plurality of word lines and the plurality of bit lines; and
dicing the wafer stack into a plurality of MRAM dies.

19. The method of claim 18, further comprising forming a die underfill between the bonded first MRAM wafer and the second MRAM wafer.

20. The method of claim 18, wherein bonding the first MRAM wafer and the second MRAM wafer comprises:
fabricating a plurality of through-silicon vias (TSVs) in the first MRAM wafer and the second MRAM wafer;
fabricating micro-pads on the plurality of TSVs; and
bonding the first MRAM wafer and the second MRAM wafer through the micro-pads and a plurality of micro-bumps.
